(19) United States
(12) Patent Application Publication
(10) Pub. No.: US 2009/0154126 A1
(43) Pub. Date: Jun. 18, 2009

(54) SEMICONDUCTOR DEVICE AND METHOD FOR MANUFACTURING THE SAME

(75) Inventors: Nozomi SHIMOISHIZAKA, Kyoto (JP); Kouichi NAGAO, Kyoto (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Osaka (JP)

(21) Appl. No.: 12/330,167

(22) Filed: Dec. 8, 2008

(30) Foreign Application Priority Data
Dec. 12, 2007 (JP) 2007-321210

(51) Int. Cl. H01L 23/498; H01L 21/50

(52) U.S. Cl. 361/772; 438/121; 257/E21.499

(57) ABSTRACT

A wiring board includes a first bonding wiring array that is formed by extending conductor wirings, and that extends from an external side of a semiconductor element region and is bonded individually to a first element electrode array of a semiconductor element, and a second bonding wiring array that extends from the external side of the semiconductor element region and is bonded individually to a second element electrode array of the semiconductor element. A pitch of the individual conductor wirings constituting the first bonding wiring array varies continuously so as to be wider than a pitch of the first element electrode array on the external side of the semiconductor element region and narrower than that of the first element electrode array at a front end on a center side of the semiconductor element, and a pitch of the individual conductor wirings constituting the second bonding wiring array varies continuously so as to be narrower than a pitch of the second element electrode array on the external side of the semiconductor element region and wider than that of the second element electrode array at a front end on the center side of the semiconductor element. In bare chip mounting by flip chip or ILB such as COF, the displacement between the semiconductor element and the electrode caused by a dimensional change of the wiring board can be alleviated.

### BACKGROUND OF THE INVENTION

1. Field of the Invention

The present invention relates to a semiconductor device having a configuration in which a semiconductor element is bonded to a wiring board, and a method for manufacturing the same.

2. Description of Related Art

A semiconductor device in which a semiconductor element is placed on a wiring board such that bonding wirings formed on the wiring board and element electrodes on the semiconductor element are bonded and a method for manufacturing the same have been known. In many cases, inexpensive organic materials are used primarily for the wiring board. The dimensional changes of the organic materials due to variations in temperature and humidity generally are greater than those of inorganic materials such as silicon and glass. This has hampered the scaling down of bonding pitches with a semiconductor element formed of silicon or the like and a liquid crystal panel, etc. formed of glass or the like.

For example, in a COF package for liquid crystal whose bonding has become relatively finer currently, a mass-producible level of the bonding pitch between a polyimide wiring board and a semiconductor element is about 30 μm, and that between a polyimide wiring board and a liquid crystal panel is about 50 μm. In order to achieve bonding with a still smaller pitch, a method has to be devised for absorbing the dimensional change of the wiring board. Accordingly, not only a dimensional adjustment due to temperature or humidity but also a method for absorbing the dimensional change by the structure of a bonded part has been devised (for example, see JP 3357296 B).

In the following, a conventional semiconductor device and a method for manufacturing the same will be described with reference to FIGS. 11A to 11C. In FIG. 11A, a wiring board 44 includes an insulating base 41, conductor wirings 42 formed on the insulating base 41 and a bonding wiring array 43. The bonding wiring array 43 is formed by extending the conductor wirings 42. On a principal surface of a semiconductor element 45 mounted on the wiring board 44, element electrodes 46 are formed. The element electrodes 46 are formed so as to be inclined outwardly from the center of the semiconductor element 45, and are bonded in such a manner as to cross the bonding wiring array 43.

In the conventional semiconductor device, as shown in FIG. 11B, even when the dimension of the wiring board 44 along a Y direction increases by 2y from a design value Y0 and the pitch of the bonding wiring array 43 increases, the bonding wiring array 43 crosses the element electrodes 46. Thus, the bonding wiring array 43 can be bonded to the element electrodes 46 without any displacement. Likewise, the bonding can be achieved also in the case where the dimension of the wiring board 44 along the Y direction decreases from the design value Y0.

However, in the conventional semiconductor device, as shown in FIG. 11C, when the dimension of the wiring board 44 along the Y direction increases further by 2y′, which is larger than the distance in the case of FIG. 11B, the bonding wiring array 43 no longer crosses the element electrodes 46. This has caused a problem in that the bonding wiring array 43 cannot be bonded to the element electrodes 46.

### SUMMARY OF THE INVENTION

It is an object of the present invention to solve the conventional problem described above and to provide a semiconductor device in which a bonding wiring array and an element electrode array can be bonded to each other without substantial displacement while, in practical use, not being restricted by a dimensional change amount of a wiring board, and a method for manufacturing the same.

A semiconductor device with a first configuration according to the present invention includes a wiring board having an insulating base and a plurality of conductor wirings formed on a surface of the insulating base, a semiconductor element mounted on the wiring board, a first element electrode array, provided along a first side of the semiconductor element, on a principal surface of the semiconductor element, a second element electrode array, provided along a second side that is opposed to the first side, on the principal surface of the semiconductor element, a first bonding wiring array that is formed by extending the conductor wirings, and that extends from an external side of a semiconductor element region of the insulating base in which the semiconductor element is placed, crosses the first side of the semiconductor element and is bonded individually to the first element electrode array, and a second bonding wiring array that is formed by extending the conductor wirings, and that extends from the external side of the semiconductor element region, crosses the second side of the semiconductor element and is bonded individually to the second element electrode array. A pitch of the individual conductor wirings constituting the first bonding wiring array varies continuously so as to be wider than a pitch of the first element electrode array on the external side of the semiconductor element region and narrower than that of the first element electrode array at a front end on a center side of the semiconductor element. A pitch of the individual conductor wirings constituting the second bonding wiring array varies continuously so as to be narrower than a pitch of the second element electrode array on the external side of the semiconductor element region and wider than that of the second element electrode array at a front end on the center side of the semiconductor element.

Also, a method for manufacturing a semiconductor device according to the present invention includes: preparing a semiconductor element whose principal surface is provided with a first element electrode array that is provided along a first side and a second element electrode array that is provided along a second side opposed to the first side; preparing a wiring board that has an insulating base and a plurality of conductor wirings formed on a surface of the insulating base, and includes a first bonding wiring array formed by extending the conductor wirings so as to have a wider pitch than the first element electrode array on an external side of a semiconductor element region in which the semiconductor element is placed and a narrower pitch than the first element electrode array at a front end on a center side of the semiconductor element and a second bonding wiring array formed by extending the conductor wirings so as to have a narrower pitch than the second element electrode array on the external side of the semiconductor element region and a wider pitch than the second element electrode array at a front end on the center side of the semiconductor element; and if a dimensional change of the wiring board occurs in a direction parallel with the first side of the semiconductor element when placing the semiconductor element on the wiring board, moving the semiconductor element from a reference position in a direction perpendicular to the first side along the direction by a distance proportional to an amount of the dimensional change, and bonding the first bonding wiring array and the first element electrode array on the one hand and the second bonding wiring array and the second element electrode array on the other hand at a position where a pitch of the first bonding wiring array is equal to that of the first element electrode array and a pitch of the second bonding wiring array is equal to that of the second element electrode array.

A semiconductor device with a second configuration according to the present invention includes a wiring board having an insulating base and a plurality of conductor wirings formed on a surface of the insulating base, a semiconductor element mounted on the wiring board, a first element electrode array, provided along a first side of the semiconductor element, on a principal surface of the semiconductor element, a second element electrode array, provided along a second side that is opposed to the first side, on the principal surface of the semiconductor element, a first bonding wiring array that is formed by extending the conductor wirings, and that extends from an external side of a semiconductor element region of the insulating base in which the semiconductor element is placed, crosses the first side of the semiconductor element and is bonded individually to the first element electrode array, and a second bonding wiring array that is formed by extending the conductor wirings, and that extends from the external side of the semiconductor element region, crosses the second side of the semiconductor element and is bonded individually to the second element electrode array. A pitch of the individual conductor wirings constituting the first bonding wiring array and the second bonding wiring array is even. Each of element electrodes constituting the first element electrode array has a slender shape whose longitudinal direction is oriented to cross the first side and the second side, and a pitch of the element electrodes varies continuously so as to be wider than the pitch of the individual conductor wirings constituting the first bonding wiring array on an outer edge side of the semiconductor element and narrower than that of the individual conductor wirings at a front end on a center side of the semiconductor element. Each of the element electrodes constituting the second element electrode array has a slender shape whose longitudinal direction is oriented to cross the first side and the second side, and a pitch of the element electrodes varies continuously so as to be narrower than the pitch of the individual conductor wirings constituting the second bonding wiring array on the outer edge side of the semiconductor element and wider than that of the individual conductor wirings at a front end on the center side of the semiconductor element.

A semiconductor device with a third configuration according to the present invention includes a first wiring board having a first insulating base, a plurality of conductor wirings formed on a surface of the first insulating base, and a first external electrode array formed by extending the plurality of conductor wirings and arranging them at one end of the first insulating base, a semiconductor element that is mounted on the first wiring board and has an element electrode electrically connected to the plurality of conductor wirings, and a second wiring board having a second insulating base, a plurality of conductor wirings formed on a surface of the second insulating base, and a second external electrode array formed by extending the plurality of conductor wirings and arranging them at one end of the second insulating base. A pitch of the first external electrode array is formed so as to increase from a center of the first wiring board toward a side provided with the first external electrode array, and a pitch of the second external electrode array is formed so as to decrease from a center of the second wiring board toward a side provided with the second external electrode array. The side of the first wiring board provided with the first external electrode array and the side of the second wiring board provided with the second external electrode array are opposed to each other, and the first external electrode array and the second external electrode array are bonded to each other in a portion where their pitches are equal.

A semiconductor device with a fourth configuration according to the present invention includes a wiring board including an insulating base, a plurality of conductor wirings formed on the insulating base, and a testing electrode array formed by extending the plurality of conductor wirings, and a semiconductor element that is mounted on the wiring board and has an element electrode electrically connected to the plurality of conductor wirings. A pitch of the testing electrode array is formed so as to be equal to a pitch of testing probes for testing an electrical property of the wiring board at a reference position in contact with the testing probes and become wider than that of the testing probes as a distance from the reference position increases in one direction and become narrower than that of the testing probes as the distance from the reference position increases in a direction opposite to the one direction.

In accordance with the semiconductor device according to the present invention and the method for manufacturing the same, a portion in which the pitch of the bonding wiring array is wider than the pitch of the semiconductor element electrodes and a portion in which the former is narrower than the latter are provided continuously, and the directions in which the pitch of the bonding wiring array varies with respect to the two sides of the semiconductor element are the same. In this way, if a dimensional change occurs in the direction parallel with the first side when placing the semiconductor element on the wiring board, the semiconductor element can be moved along the direction perpendicular to the first side by the distance proportional to the amount of the dimensional change, thereby making the pitch of the bonding wiring array and that of the element electrode array equal. Consequently, the bonding wiring array and the element electrode array can be bonded to each other without substantial displacement while, in practical use, not being restricted by a dimensional change amount of the wiring board.

### BRIEF DESCRIPTION OF THE DRAWINGS

FIG. 1 is a plan view showing a semiconductor device according to Embodiment 1 of the present invention and its effect.

FIG. 2 is a plan view showing a semiconductor device according to Embodiment 2 of the present invention and the semiconductor device according to Embodiment 1 for comparison.

FIG. 3 is a plan view showing a semiconductor device according to Embodiment 3 of the present invention.

FIGS. 4A and 4B are enlarged views of a main portion of the semiconductor device according to Embodiment 3.

FIG. 5 is a plan view showing a semiconductor device according to Embodiment 3.

FIG. 6 is a plan view showing a semiconductor device according to Embodiment 4 of the present invention and its effect.

FIG. 7 is a plan view showing a semiconductor device according to Embodiment 5 of the present invention and its effect.

FIG. 8 is a perspective view showing an example of protruding electrodes used in Embodiment 5.

FIG. 9 is a plan view showing a semiconductor device according to Embodiment 6 of the present invention and its effect.

FIG. 10 is a plan view showing a semiconductor device according to Embodiment 7 of the present invention and its effect.

FIGS. 11A, 11B and 11C are plan views showing a conventional semiconductor device.

### DETAILED DESCRIPTION OF THE INVENTION

The present invention can be in the following modes based on the configurations described above.

That is, in the semiconductor device with the first configuration, the first bonding wiring array and the second bonding wiring array further can extend toward a center of the semiconductor element from respective positions at which they are bonded to the first element electrode array and the second element electrode array.

Also, one of a first angle at which an arbitrary first conductor wiring constituting the first bonding wiring array crosses the first side of the semiconductor element and a second angle at which a second conductor wiring that constitutes the second bonding wiring array and is formed at a position opposed to the first conductor wiring crosses the second side of the semiconductor element can be smaller than the other.

Further, a first angle at which an arbitrary first conductor wiring constituting the first bonding wiring array crosses the first side of the semiconductor element and a second angle at which a second conductor wiring that constitutes the second bonding wiring array and is formed at a position opposed to the first conductor wiring crosses the second side of the semiconductor element can be equal.

Moreover, each of element electrodes constituting the first element electrode array and the second element electrode array can be a columnar protruding electrode.

Additionally, in the method for manufacturing a semiconductor device, a first identification mark and a second identification mark can be provided on the wiring board so as to be spaced away from each other by a reference distance in a direction along the first side of the semiconductor element, and the dimensional change of the wiring board in the direction parallel with the first side of the semiconductor element can be determined by a variation in a distance between the first identification mark and the second identification mark from the reference distance in the direction along the first side.

The following is a description of embodiments of the present invention, with reference to the accompanying drawings.

### Embodiment 1

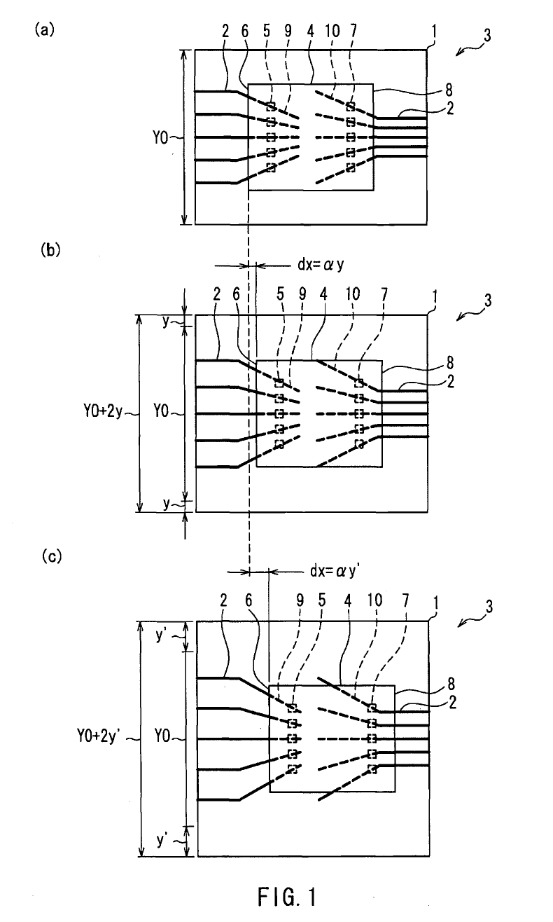

FIG. 1(a) is a plan view showing a semiconductor device according to Embodiment 1 of the present invention. In FIG. 1(a), a wiring board 3 has an insulating base 1 and conductor wirings 2 formed on the surface of the insulating base 1. The wiring board 3 further is provided with a first bonding wiring array 9 and a second bonding wiring array 10. On a principal surface of a semiconductor element 4 mounted on the wiring board 3, a first element electrode array 5 is arranged along a first side 6 of the semiconductor element 4, and a second element electrode array 7 is arranged along a second side 8 that is opposed to the first side 6.

The first bonding wiring array 9 is formed by extending the conductor wirings 2. The first bonding wiring array 9 extends from an external side of a region of the insulating base 1 in which the semiconductor element 4 is placed, crosses the first side 6 of the semiconductor element 4, is bonded individually to the first element electrode array 5 and further extends toward the center of the semiconductor element 4.

The second bonding wiring array 10 is formed by extending the conductor wirings 2. The second bonding wiring array 10 extends from the external side of the region of the insulating base 1 in which the semiconductor element 4 is placed, crosses the second side 8 of the semiconductor element 4, is bonded individually to the second element electrode array 7 and further extends toward the center of the semiconductor element 4.

The pitch of the individual conductor wirings 2 constituting the first bonding wiring array 9 is made to vary continuously so as to be wider than the pitch of the first element electrode array 5 on the external side of the region where the semiconductor element 4 is placed, equal to that of the first element electrode array 5 at bonding positions with the first element electrode array 5 and narrower than that of the first element electrode array 5 on a center side of the semiconductor element 4 with respect to the bonding positions with the first element electrode array 5.

On the other hand, the pitch of the individual conductor wirings 2 constituting the second bonding wiring array 10 is made to vary continuously so as to be narrower than the pitch of the second element electrode array 7 on the external side of the region where the semiconductor element 4 is placed, equal to that of the second element electrode array 7 at bonding positions with the second element electrode array 7 and wider than that of the second element electrode array 7 on the center side of the semiconductor element 4 with respect to the bonding positions with the second element electrode array 7.

Here, the description is directed to an example of a COF (Chip On Film) package used for a general liquid crystal package. In this case, the insulating base 1 is formed of a polyimide film with a thickness of about 40 μm, the conductor wirings 2 are formed of Cu wirings with a thickness of about 8 μm and a width of about 15 μm on which Sn is electroless plated and the element electrode arrays 5 and 7 are formed of Au electroplated bumps with a height of about 15 μm, for instance.

Now, the method for manufacturing a semiconductor device according to the present embodiment will be described with reference to FIG. 1(b) and FIG. 1(c). In FIG. 1(b) and FIG. 1(c), elements that are the same as those in the semiconductor device shown in FIG. 1(a) are assigned the same reference signs. It should be noted that a direction parallel with the first side 6 of the semiconductor element 4 is designated as a Y direction and a direction perpendicular thereto is designated as an X direction.

FIG. 1(b) illustrates the case in which the dimension of the wiring board 3 along the Y direction has increased by 2y from the dimension shown in FIG. 1(a). In this case, when placing the semiconductor element 4 on the wiring board 3, the semiconductor element 4 is moved from the position of FIG. 1(a) (reference position) along the X direction perpendicular to the first side 6 by a distance dx=αy proportional to y, which is the dimensional change in the Y direction. This makes it possible to adjust a positional relationship so that the pitch of the first bonding wiring array 9 is equal to that of the first element electrode array 5 and the pitch of the second bonding wiring array 10 is equal to that of the second element electrode array 7. As a result, the first bonding wiring array 9 and the first element electrode array 5 on the one hand and the second bonding wiring array 10 and the second element electrode array 7 on the other hand can be bonded in an appropriate relationship with each other.

FIG. 1(c) illustrates the case in which the dimension of the wiring board 3 along the Y direction has increased further from the dimension shown in FIG. 1(b). In this case, when placing the semiconductor element 4 on the wiring board 3, the semiconductor element 4 also is moved from the position of FIG. 1(a) along the direction perpendicular to the first side 6 by a distance dx=αy′ proportional to y′, which is the dimensional change in the Y direction. This makes it possible to adjust positional relationship so that the pitch of the first bonding wiring array 9 is equal to that of the first element electrode array 5 and the pitch of the second bonding wiring array 10 is equal to that of the second element electrode array 7. As a result, the first bonding wiring array 9 and the first element electrode array 5 on the one hand and the second bonding wiring array 10 and the second element electrode array 7 on the other hand can be bonded in an appropriate relationship with each other.

As described above, in accordance with the present embodiment, the first and second bonding wiring arrays 9 and 10 and the first and second element electrode arrays 5 and 7 can be bonded without substantial displacement while, in practical use, not being restricted by a dimensional change amount of the wiring board along the Y direction.

In general, since y and y′, which are the dimensional changes in the Y direction, do not cause much difference in a manufacturing lot of the wiring board, the moving amount dx can be set per lot based on the results of measuring the dimension at the time of a delivery inspection or an acceptance inspection of the wiring board.

The example of FIG. 1 has illustrated the configuration in which the angles of the conductor wirings of the first bonding wiring array 9 and the second bonding wiring array 10 at corresponding positions are equal to each other. This is a mode when there is a dimensional change in the Y direction but substantially no dimensional change in the X direction. As described later, when there also is a substantial dimensional change in the X direction, the angles of the first bonding wiring array 9 and the second bonding wiring array 10 have to be adjusted accordingly.

### Embodiment 2

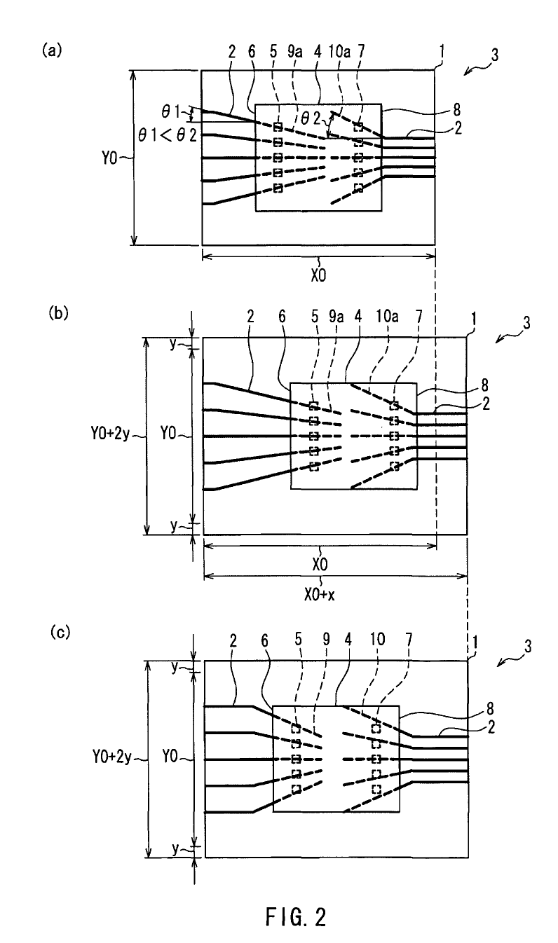

FIGS. 2(a) and 2(b) are plan views showing a semiconductor device according to Embodiment 2 of the present invention. In these figures, elements that are the same as those of the semiconductor device shown in FIG. 1(a) are assigned the same reference signs, and the repeated description thereof will be omitted.

The present embodiment is different from Embodiment 1 in that, as shown in FIG. 2(a), a first angle θ1 at which any one of the first conductor wirings 9a constituting the first bonding wiring array 9 crosses the first side 6 of the semiconductor element 4 is smaller than a second angle θ2 at which a second conductor wiring 10a that constitutes the second bonding wiring array 10 and is formed at a position opposed to the first conductor wiring 9a crosses the second side 8 of the semiconductor element 4.

In general, the change in the dimension of the wiring board 3 occurs in both of the Y direction and the X direction. As shown in FIG. 2(b), when the dimension of the wiring board 3 along the Y direction has increased by 2y and the dimension thereof along the X direction has increased by x at the same time, the semiconductor element 4 is moved from the position of FIG. 2(a) along the X direction by a distance proportional to y. This makes it possible to adjust a positional relationship so that the pitch of the first bonding wiring array 9 is equal to that of the first element electrode array 5 and the pitch of the second bonding wiring array 10 is equal to that of the second element electrode array 7. As a result, the first bonding wiring array 9 and the first element electrode array 5 on the one hand and the second bonding wiring array 10 and the second element electrode array 7 on the other hand can be bonded in an appropriate relationship with each other.

In other words, in the semiconductor device according to Embodiment 2 of the present invention, the first and second bonding wiring arrays 9 and 10 and the first and second element electrode arrays 5 and 7 can be bonded with no displacement while coping with the dimensional change of the wiring board also along the X direction.

Now, for comparison, FIG. 2(c) illustrates the case in which the dimension in the X direction has increased by x similarly to the case of FIG. 2(b) in the semiconductor device according to Embodiment 1 of the present invention, which does not cope with the dimensional change of the wiring board 3 along the X direction, on the same scale. When the semiconductor element 4 is moved to a position at which the pitch of the first bonding wiring array 9 match that of the first element electrode array 5, the second bonding wiring array 10 and the second element electrode array 7 are displaced from each other and cannot be bonded to each other.

Incidentally, the relationship between the first angle θ1 and the second angle θ2 may be reversed from that in the above configuration. In that case, it is appropriate to reverse the right and left of the reference position of the semiconductor element 4 and the direction along which the semiconductor element 4 is moved in the above configuration.

### Embodiment 3

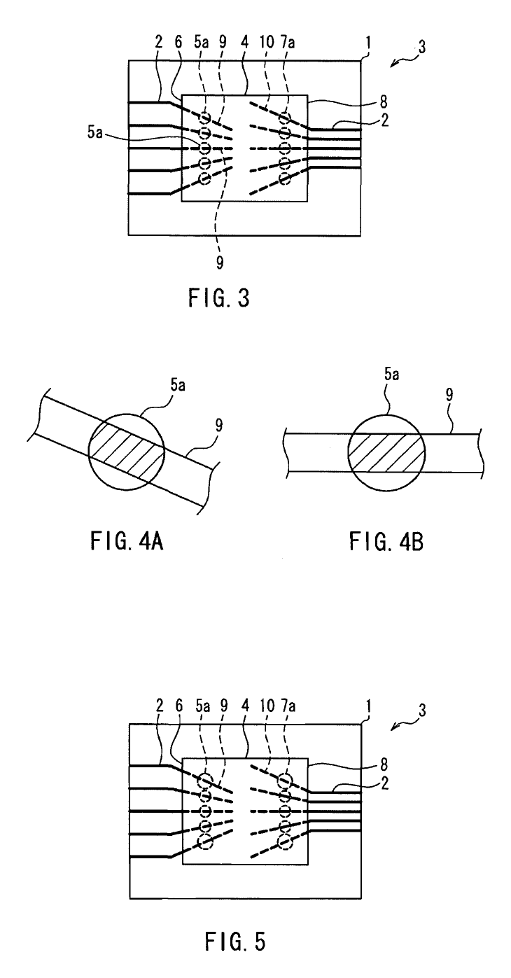

FIG. 3 is a plan view showing a semiconductor device according to Embodiment 3 of the present invention, and FIGS. 4A and 4B are plan views showing enlarged portions of FIG. 3. In FIGS. 3, 4A and 4B, elements that are the same as those in the semiconductor device shown in FIG. 1(a) are assigned the same reference signs, and the repeated description thereof will be omitted. It should be noted that the semiconductor device in FIGS. 3, 4A and 4B is different from that shown in FIG. 1(a) in that first element electrodes 5a and second element electrodes 7a have a columnar shape.

In Embodiment 1, the angles at which the first and second element electrodes 5a and 7a cross the first and second bonding wiring arrays 9 and 10 vary with their positions arranged on the semiconductor element 4 as illustrated in FIG. 1(a) to FIG. 1(c), and therefore, the bonded areas of the first and second element electrodes 5a and 7a and the first and second bonding wiring arrays 9 and 10 also vary. In contrast, by forming the first and second element electrodes 5a and 7a to have a columnar shape as in the present embodiment, the bonded area (a hatched portion) of the first element electrode 5a and the first bonding wiring array 9 is substantially constant regardless of the angle at which the first element electrode 5a crosses the first bonding wiring array 9 as shown in FIGS. 4A and 4B. In other words, the bonded area is determined substantially by the diameter of the column forming the first element electrode 5a and the width of the first bonding wiring array 9.

Accordingly, the bonded area could be made equal at all the positions as shown in FIGS. 4A and 4B. However, for example, as shown in FIG. 5, it also is possible to increase the bonded area by increasing the diameter of the column toward end portions of the semiconductor element 4 in which large stress is applied after bonding, so that the bonding strength can be secured.

Incidentally, when Au electroplating is used, the first element electrode 5a and the second element electrode 7a easily can be formed to have a columnar shape by employing a circular exposure mask.

### Embodiment 4

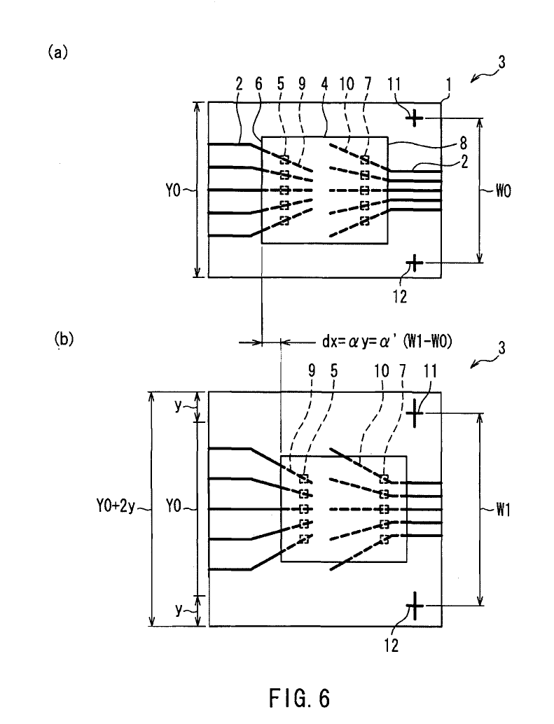

FIG. 6 is a plan view showing a method for manufacturing a semiconductor device according to Embodiment 4 of the present invention. In FIG. 6, elements that are the same as those of the semiconductor device shown in FIG. 1(a) are assigned the same reference signs, and the repeated description thereof will be omitted. In the configuration of the present embodiment, a first identification mark 11 and a second identification mark 12 are formed on the insulating base 1. The distance between the first identification mark 11 and the second identification mark 12 in the Y direction along the first side 6 of the semiconductor element 4 is W0.

FIG. 6(b) illustrates the case in which the dimension of the wiring board 3 along the Y direction has increased by 2y from the dimension shown in FIG. 6(a). In this case, the distance between the first identification mark 11 and the second identification mark 12 in the Y direction is W1, and the dimensional change y of the wiring board 3 in the direction parallel with the first side 6 of the semiconductor element 4 is proportional to (W1-W0).

Thus, when placing the semiconductor element 4 on the wiring board 3, the semiconductor element 4 is moved from the position of FIG. 6(a) along the X direction perpendicular to the first side 6 by a distance dx=αy=α′(W1−W0) proportional to y, which is the dimensional change in the Y direction. This makes it possible to adjust a positional relationship so that the pitch of the first bonding wiring array 9 is equal to that of the first element electrode array 5 and the pitch of the second bonding wiring array 10 is equal to that of the second element electrode array 7. As a result, the first bonding wiring array 9 and the first element electrode array 5 on the one hand and the second bonding wiring array 10 and the second element electrode array 7 on the other hand can be bonded in an appropriate relationship with each other.

The present Embodiment 4 makes it possible to set the moving distance dx of the semiconductor element 4 to an optimal value according to the variation in the distance between the first identification mark 11 and the second identification mark 12 of the wiring board 3 used for an actual bonding. Accordingly, compared with Embodiment 1 in which dx has been set per lot, the positional accuracy for bonding can be improved further.

### Embodiment 5

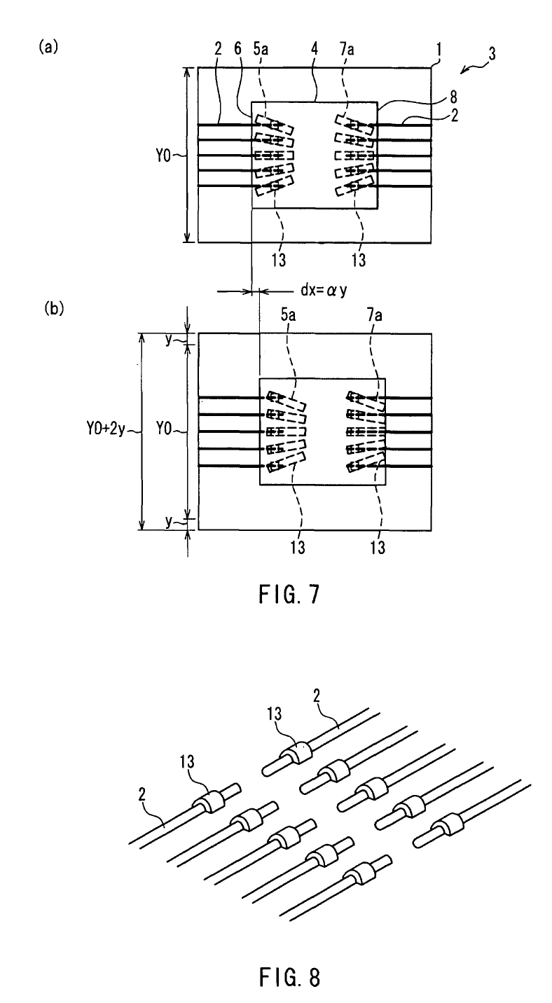

Incidentally, the first bonding wiring array 9 and the second bonding wiring array 10 on the wiring board 3 have a certain angle in Embodiments 1 to 4. In contrast, the first element electrode array 5a and the second element electrode array 7a on the semiconductor element 4 may have an angle as shown in FIG. 7.

In other words, as shown in FIG. 7(a), the conductor wirings 2 are formed so as to extend linearly with a constant pitch, and these wirings extend from a left external side and a right external side of the region where the semiconductor element 4 is placed, respectively cross the first side 6 and the second side 8 of the semiconductor element 4, and are bonded individually to the first element electrode array 5a and the second element electrode array 7a. Each of element electrodes constituting the first element electrode array 5a and the second element electrode array 7a has a slender shape whose longitudinal direction is oriented to cross the first side 6 and the second side 8.

The pitch of the individual element electrodes constituting the first element electrode array 5a varies continuously so as to be wider than that of the conductor wirings 2 in the vicinity of an outer edge of the semiconductor element 4, equal to that of the conductor wirings 2 at bonding positions with the conductor wirings 2 and narrower than that of the conductor wirings 2 on a center side of the semiconductor element 4 with respect to the bonding positions with the conductor wirings 2.

On the other hand, the pitch of the individual element electrodes constituting the second element electrode array 7a varies continuously so as to be narrower than that of the conductor wirings 2 in the vicinity of an outer edge of the semiconductor element 4, equal to that of the conductor wirings 2 at bonding positions with the conductor wirings 2 and wider than that of the conductor wirings 2 on the center side of the semiconductor element 4 with respect to the bonding positions with the conductor wirings 2.

FIG. 7(b) illustrates the case in which the dimension of the wiring board 3 along the Y direction has increased by 2y from the dimension shown in FIG. 7(a). In this case, when placing the semiconductor element 4 on the wiring board 3, the semiconductor element 4 is moved from the position of FIG. 7(a) along the X direction perpendicular to the first side 6 by a distance dx=αy proportional to y, which is the dimensional change in the Y direction. This makes it possible to adjust a positional relationship so that the pitches of the first element electrode array 5a and the second element electrode array 7a are equal to the pitch of the conductor wirings 2. As a result, the conductor wirings 2 and the first element electrode array 5a on the one hand and the conductor wirings 2 and the second element electrode array 7a on the other hand can be bonded in an appropriate relationship with each other.

In this case, protruding electrodes 13 have to be provided on the wiring board 3 on the side of the conductor wirings 2. For example, as shown in FIG. 8, protruding electrodes 13 that are formed so as to cross the conductor wirings 2 and extend over both sides of the conductor wirings 2 on the insulating base 1 (see JP 3565835 B) may be used.

### Embodiment 6

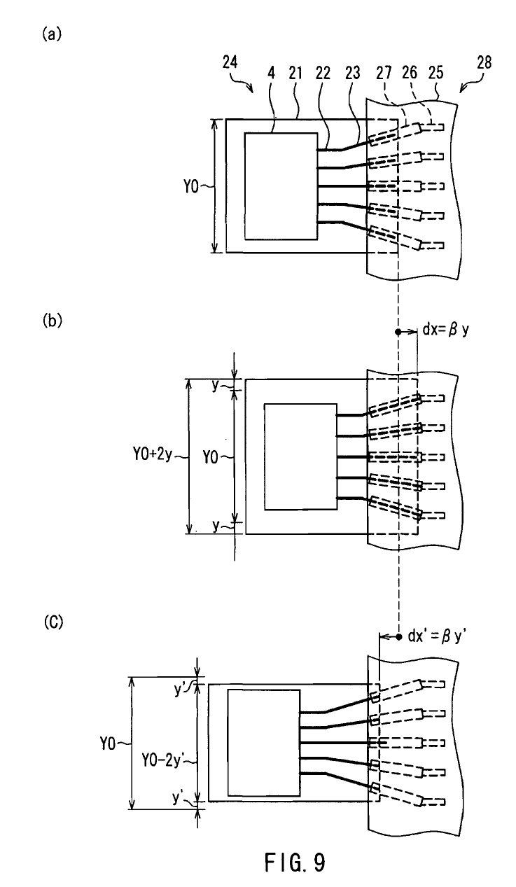

FIG. 9 is a plan view showing a semiconductor device according to Embodiment 6 of the present invention. In FIG. 9, a first wiring board 24 includes a first insulating base 21, conductor wirings 22 formed on the first insulating base 21, and a first external electrode array 23. The first external electrode array 23 is formed by extending a plurality of the conductor wirings 22 and arranging them at one end of the first insulating base 21. On this first insulating base 21, a semiconductor element 4 is mounted and connected to the conductor wirings 22, though the structure of the connection is not shown here.

A second wiring board 28 includes a second insulating base 25, conductor wirings 26 formed on the second insulating base 25, and a second external electrode array 27. The second external electrode array 27 is formed by extending a plurality of the conductor wirings 26 and arranging them at one end of the second insulating base 25.

The pitch of the first external electrode array 23 is set to increase from a center of the first wiring board 24 toward a side thereof provided with the first external electrode array 23. The pitch of the second external electrode array 27 is set to decrease from a center of the second wiring board 28 toward a side thereof provided with the second external electrode array 27. The side of the first wiring board 24 provided with the first external electrode array 23 and the side of the second wiring board 28 provided with the second external electrode array 27 are opposed to each other, and the first external electrode array 23 and the second external electrode array 27 are bonded to each other in a portion where their pitches are equal.

The present embodiment is directed to an example in which the first wiring board 24 is a COF package for liquid crystal formed of polyimide and the second wiring board is a glass substrate for liquid crystal. A Cu foil plated with Sn is used so as to serve as the first external electrode array 23, Al is used so as to serve as the second external electrode array 27, and they are bonded to each other using an ACF (Anisotropic Conductive Film).

In the present embodiment, it also is possible to achieve the same function by replacing the first wiring board 24 with the glass substrate for liquid crystal and the second wiring board with the COF package for liquid crystal and applying them in completely the same manner.

The method for manufacturing a semiconductor device according to the present embodiment is characterized similarly to Embodiment 1. FIG. 9(b) illustrates the case in which the dimension of the wiring board 24 along the Y direction has increased by 2y from the dimension shown in FIG. 9(a). FIG. 9(c) illustrates the case in which the dimension of the wiring board 24 along the Y direction has decreased by 2y′ from the dimension shown in FIG. 9(a).

In both cases, by moving the position of the wiring board 24 along the X direction by a distance dx=βy or dx′=βy′ proportional to the dimensional change in the Y direction, the first external electrode array 23 and the second external electrode array 27 can be bonded to each other in a portion where their pitches are equal.

In the present embodiment, neither the first external electrode array 23 nor the second external electrode array 27 has to be provided with any protruding electrodes unlike Embodiments 1 to 4. The present embodiment is applicable to the bonding of the COF package or the like and the glass substrate for liquid crystal as described above.

### Embodiment 7

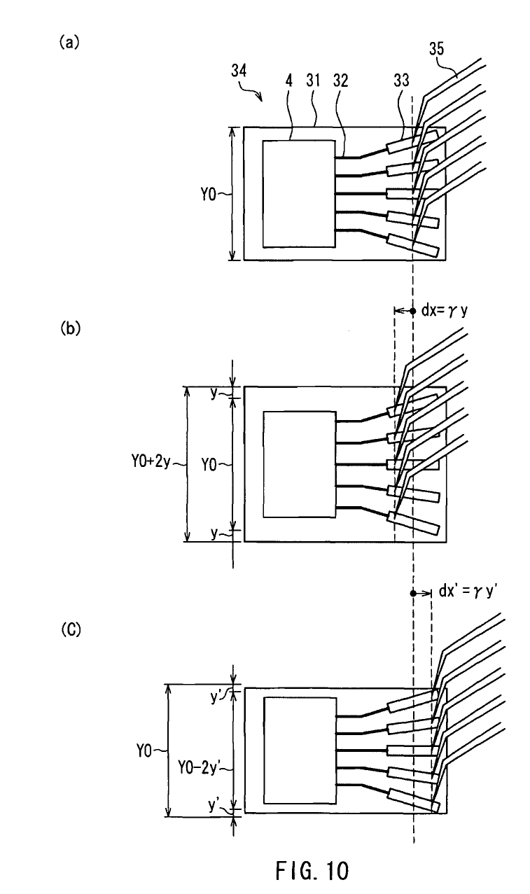

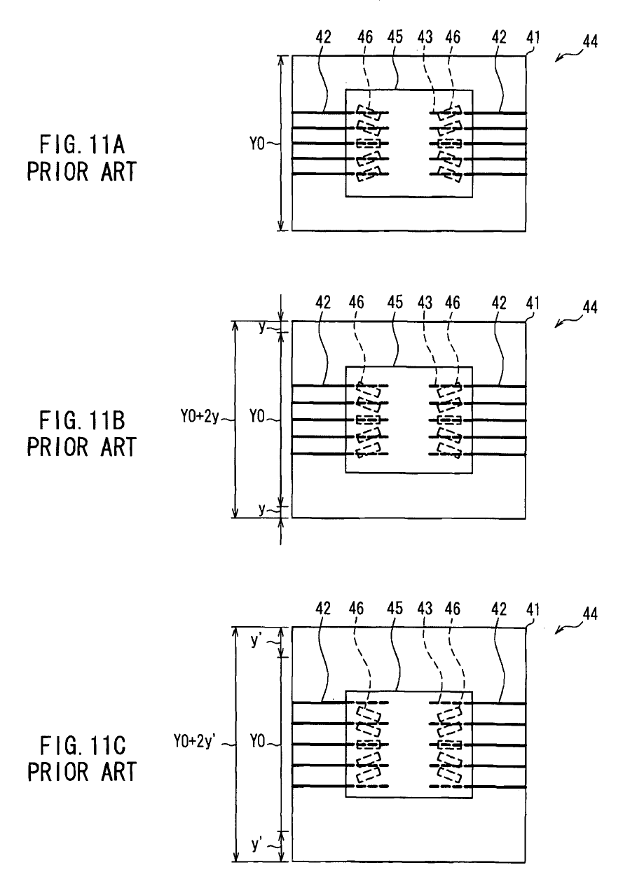

FIG. 10 is a plan view showing a semiconductor device according to Embodiment 7 of the present invention. In FIG. 10, a wiring board 34 includes an insulating base 31, conductor wirings 32 formed on the insulating base 31, and a testing electrode array 33. The testing electrode array 33 is formed by extending a plurality of the conductor wirings 32. Numeral 35 denotes testing probes to be brought into contact with the testing electrode array 33. Further, on the insulating base 31, a semiconductor element 4 is mounted and connected to the conductor wirings 32, though the structure of the connection is not shown here.

The pitch of the testing electrode array 33 is designed so as to be equal to that of the testing probes 35 at a position in contact with the testing probes 35, become wider than that of the testing probes 35 as the distance from that contact position increases in one direction and become narrower than that of the testing probes 35 as the distance from the contact position increases in a direction opposite to that direction.

The present embodiment is directed to an example in which the wiring board 34 is a part constituting the COF package for a liquid crystal display. A Cu foil plated with Sn is used so as to serve as the testing electrode array 33, and tungsten is used so as to serve as the testing probes 35, whereby electrical testing is carried out.

In a method for testing a semiconductor device according to the present embodiment, the method of matching the testing probes 35 with the testing electrode array 33 so as to bring them into contact with each other is similar to the method of bringing the first bonding wiring array 9 and the first element electrode array 5 on the one hand and the second bonding wiring array 10 and the second element electrode array 7 on the other hand into an appropriate matching relationship with each other in Embodiment 1. In other words, FIG. 10(b) illustrates the case in which the dimension of the wiring board 34 along the Y direction has increased by 2y from the dimension shown in FIG. 10(a), and FIG. 10(c) illustrates the case in which the dimension of the wiring board 34 along the Y direction has decreased by 2y′ from the dimension shown in FIG. 10(a).

In both cases, by moving the position of the wiring board 34 along the X direction by a distance dx proportional to the dimensional change in the Y direction, the testing electrode array 33 and the testing probes 35 can be brought into contact with each other in a portion where their pitches are equal.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device comprising:
a wiring board having an insulating base and a plurality of conductor wirings formed on a surface of the insulating base;
a semiconductor element mounted on the wiring board;
a first element electrode array, provided along a first side of the semiconductor element, on a principal surface of the semiconductor element;
a second element electrode array, provided along a second side that is opposed to the first side, on the principal surface of the semiconductor element;
a first bonding wiring array that is formed by extending the conductor wirings, and that extends from an external side of a semiconductor element region of the insulating base in which the semiconductor element is placed, crosses the first side of the semiconductor element and is bonded individually to the first element electrode array; and
a second bonding wiring array that is formed by extending the conductor wirings, and that extends from the external side of the semiconductor element region, crosses the second side of the semiconductor element and is bonded individually to the second element electrode array;
wherein a pitch of the individual conductor wirings constituting the first bonding wiring array varies continuously so as to be wider than a pitch of the first element electrode array on the external side of the semiconductor element region and narrower than that of the first element electrode array at a front end on a center side of the semiconductor element, and
a pitch of the individual conductor wirings constituting the second bonding wiring array varies continuously so as to be narrower than a pitch of the second element electrode array on the external side of the semiconductor element region and wider than that of the second element electrode array at a front end on the center side of the semiconductor element.

2. The semiconductor device according to claim 1, wherein the first bonding wiring array and the second bonding wiring array further extend toward a center of the semiconductor element from respective positions at which they are bonded to the first element electrode array and the second element electrode array.

3. The semiconductor device according to claim 1, wherein one of a first angle at which an arbitrary first conductor wiring constituting the first bonding wiring array crosses the first side of the semiconductor element and a second angle at which a second conductor wiring that constitutes the second bonding wiring array and is formed at a position opposed to the first conductor wiring crosses the second side of the semiconductor element is smaller than the other.

4. The semiconductor device according to claim 1, wherein a first angle at which an arbitrary first conductor wiring constituting the first bonding wiring array crosses the first side of the semiconductor element and a second angle at which a second conductor wiring that constitutes the second bonding wiring array and is formed at a position opposed to the first conductor wiring crosses the second side of the semiconductor element are equal.

5. The semiconductor device according to claim 1, wherein each of element electrodes constituting the first element electrode array and the second element electrode array is a columnar protruding electrode.

6. A method for manufacturing a semiconductor device, comprising:
preparing a semiconductor element whose principal surface is provided with a first element electrode array that is provided along a first side and a second element electrode array that is provided along a second side opposed to the first side;
preparing a wiring board that has an insulating base and a plurality of conductor wirings formed on a surface of the insulating base, and comprises a first bonding wiring array formed by extending the conductor wirings so as to have a wider pitch than the first element electrode array on an external side of a semiconductor element region in which the semiconductor element is placed and a narrower pitch than the first element electrode array at a front end on a center side of the semiconductor element and a second bonding wiring array formed by extending the conductor wirings so as to have a narrower pitch than the second element electrode array on the external side of the semiconductor element region and a wider pitch than the second element electrode array at a front end on the center side of the semiconductor element; and
if a dimensional change of the wiring board occurs in a direction parallel with the first side of the semiconductor element when placing the semiconductor element on the wiring board, moving the semiconductor element from a reference position in a direction perpendicular to the first side along the direction by a distance proportional to an amount of the dimensional change, and bonding the first bonding wiring array and the first element electrode array on the one hand and the second bonding wiring array and the second element electrode array on the other hand at a position where a pitch of the first bonding wiring array is equal to that of the first element electrode array and a pitch of the second bonding wiring array is equal to that of the second element electrode array.

7. The method for manufacturing a semiconductor device according to claim 6, wherein a first identification mark and a second identification mark are provided on the wiring board so as to be spaced away from each other by a reference distance in a direction along the first side of the semiconductor element, and
the dimensional change of the wiring board in the direction parallel with the first side of the semiconductor element is determined by a variation in a distance between the first identification mark and the second identification mark from the reference distance in the direction along the first side.

8. A semiconductor device comprising:
a wiring board having an insulating base and a plurality of conductor wirings formed on a surface of the insulating base;
a semiconductor element mounted on the wiring board;
a first element electrode array, provided along a first side of the semiconductor element, on a principal surface of the semiconductor element;
a second element electrode array, provided along a second side that is opposed to the first side, on the principal surface of the semiconductor element;
a first bonding wiring array that is formed by extending the conductor wirings, and that extends from an external side of a semiconductor element region of the insulating base in which the semiconductor element is placed, crosses the first side of the semiconductor element and is bonded individually to the first element electrode array; and
a second bonding wiring array that is formed by extending the conductor wirings, and that extends from the external side of the semiconductor element region, crosses the second side of the semiconductor element and is bonded individually to the second element electrode array;
wherein a pitch of the individual conductor wirings constituting the first bonding wiring array and the second bonding wiring array is even,
each of element electrodes constituting the first element electrode array has a slender shape whose longitudinal direction is oriented to cross the first side and the second side, and a pitch of the element electrodes varies continuously so as to be wider than the pitch of the individual conductor wirings constituting the first bonding wiring array on an outer edge side of the semiconductor element and narrower than that of the individual conductor wirings at a front end on a center side of the semiconductor element, and
each of element electrodes constituting the second element electrode array has a slender shape whose longitudinal direction is oriented to cross the first side and the second side, and a pitch of the element electrodes varies continuously so as to be narrower than the pitch of the individual conductor wirings constituting the second bonding wiring array on the outer edge side of the semiconductor element and wider than that of the individual conductor wirings at a front end on the center side of the semiconductor element.

9. A semiconductor device comprising:
a first wiring board having a first insulating base, a plurality of conductor wirings formed on a surface of the first insulating base, and a first external electrode array formed by extending the plurality of conductor wirings and arranging them at one end of the first insulating base;
a semiconductor element that is mounted on the first wiring board and has an element electrode electrically connected to the plurality of conductor wirings; and
a second wiring board having a second insulating base, a plurality of conductor wirings formed on a surface of the second insulating base, and a second external electrode array formed by extending the plurality of conductor wirings and arranging them at one end of the second insulating base;
wherein a pitch of the first external electrode array is formed so as to increase from a center of the first wiring board toward a side provided with the first external electrode array, and a pitch of the second external electrode array is formed so as to decrease from a center of the second wiring board toward a side provided with the second external electrode array, and
the side of the first wiring board provided with the first external electrode array and the side of the second wiring board provided with the second external electrode array are opposed to each other, and the first external electrode array and the second external electrode array are bonded to each other in a portion where their pitches are equal.

10. A semiconductor device comprising:
a wiring board including an insulating base, a plurality of conductor wirings formed on the insulating base, and a testing electrode array formed by extending the plurality of conductor wirings; and
a semiconductor element that is mounted on the wiring board and has an element electrode electrically connected to the plurality of conductor wirings;
wherein a pitch of the testing electrode array is formed so as to be equal to a pitch of testing probes for testing an electrical property of the wiring board at a reference position in contact with the testing probes and become wider than that of the testing probes as a distance from the reference position increases in one direction and become narrower than that of the testing probes as the distance from the reference position increases in a direction opposite to the one direction.
